(19) United States
(12) Patent Application Publication
(10) Pub. No.: US 2019/0157263 A1
(43) Pub. Date: May 23, 2019

(54) ASYMMETRIC TRANSIENT VOLTAGE SUPPRESSOR DEVICE AND METHODS FOR FORMATION

(71) Applicant: Littelfuse, Inc., Chicago, IL (US)

(72) Inventor: James Allan Peters, Wiltshire (GB)

(73) Assignee: Littelfuse, Inc., Chicago, IL (US)

(21) Appl. No.: 15/817,523

(22) Filed: Nov. 20, 2017

(51) Int. Cl. H01L 27/06; H01L 29/861; H01L 23/495

(52) U.S. Cl. CPC H01L 27/0676; H01L 29/66136; H01L 23/49562; H01L 29/8613

(57) ABSTRACT

A transient voltage suppression (TVS) device may include a substrate base formed in a substrate, the substrate base comprising a semiconductor of a first conductivity type. The TVS device may further include an epitaxial layer, comprising a first thickness, and disposed on the substrate base, on a first side of the substrate. The epitaxial layer may include a first epitaxial portion, the first epitaxial portion comprising the first thickness, and being formed of a semiconductor of a second conductivity type; and a second epitaxial portion, the second epitaxial portion comprising an upper region, the upper region formed of the second conductivity type, and having a second thickness less than the first thickness. A buried diffusion region may be disposed in a lower portion of the epitaxial layer in the second epitaxial region, the buried diffusion region being formed of a semiconductor of the first conductivity type, wherein the first portion is electrically isolated from the upper region of the second portion.

### BACKGROUND

### Field

Embodiments relate to the field of circuit protection devices, including fuse devices.

### Discussion of Related Art

Semiconductor devices such as transient voltage suppressor (TVS) devices may be fabricated as unidirectional devices or bidirectional devices. In the case of bidirectional devices, a first device may be fabricated on a first side of a semiconductor die (chip), while a second device may be fabricated on a second side of the semiconductor die. Bidirectional devices may include symmetric devices where the first device and second device are the same, as well as asymmetric devices, where the first device and second device differ in properties.

While such bidirectional devices provide some flexibility in independently designing electrical properties of the different devices on different sides of a semiconductor die, the packaging of such devices may be relatively complex.

With respect to these and other considerations, the present disclosure is provided.

### SUMMARY

Exemplary embodiments are directed to improved TVS devices and techniques for forming TVS devices.

In one embodiment, a transient voltage suppression (TVS) device may include: a substrate base formed in a substrate, the substrate base comprising a semiconductor of a first conductivity type; and an epitaxial layer, comprising a first thickness, and disposed on the substrate base, on a first side of the substrate. The epitaxial layer may include a first epitaxial portion, the first epitaxial portion comprising the first thickness, and being formed of a semiconductor of a second conductivity type; and a second epitaxial portion, the second epitaxial portion comprising an upper region, the upper region formed of the second conductivity type, and having a second thickness less than the first thickness. A buried diffusion region may be disposed in a lower portion of the epitaxial layer in the second epitaxial region, the buried diffusion region being formed of a semiconductor of the first conductivity type, wherein the first portion is electrically isolated from the upper region of the second portion.

In a further embodiment, a transient voltage suppression (TVS) device assembly may include a TVS device, where the TVS device comprises a substrate base formed in a substrate. The substrate base may include a semiconductor of a first conductivity type; an epitaxial layer, comprising a first thickness, and disposed on the substrate base, on a first side of the substrate. The epitaxial layer may further include a first epitaxial portion, the first epitaxial portion comprising the first thickness, and being formed of a semiconductor of a second conductivity type; a second epitaxial portion, the second epitaxial portion comprising an upper region, the upper region formed of the second conductivity type, and having a second thickness less than the first thickness, wherein a buried diffusion region is disposed in a lower region of the epitaxial layer in the second epitaxial portion, the buried diffusion region being formed of a semiconductor of the first conductivity type. The TVS device assembly may further include a leadframe, the leadframe being coupled to the TVS device on the first side of the substrate.

In a further embodiment, a method may include providing a substrate having a base layer of a first conductivity type and forming an epitaxial layer of a second conductivity type on the base layer, wherein the epitaxial layer is disposed on a first side of the substrate, and having a first thickness. The method may further include forming a first epitaxial portion and a second epitaxial portion within the epitaxial layer, wherein the first epitaxial portion is electrically isolated from the second epitaxial portion. The method may include forming a buried diffusion region in the second epitaxial portion, the buried diffusion region extending at least to an interface between the epitaxial layer and the substrate base, wherein the buried diffusion region comprises the first conductivity type, wherein the buried diffusion region defines an upper region of the second epitaxial portion, the upper region comprising the second conductivity type, and having a second thickness less than the first thickness.

### BRIEF DESCRIPTION OF THE DRAWINGS

FIG. 1 illustrates a TVS device according to embodiments of the disclosure;

FIG. 2 illustrates a TVS device assembly according to other embodiments of the disclosure; and

FIG. 3 depicts an exemplary process flow according to embodiments of the disclosure.

### DESCRIPTION OF EMBODIMENTS

The present embodiments will now be described more fully hereinafter with reference to the accompanying drawings, in which exemplary embodiments are shown. The embodiments are not to be construed as limited to the embodiments set forth herein. Rather, these embodiments are provided so that this disclosure will be thorough and complete, and will fully convey their scope to those skilled in the art. In the drawings, like numbers refer to like elements throughout.

In the following description and/or claims, the terms “on,” “overlying,” “disposed on” and “over” may be used in the following description and claims. “On,” “overlying,” “disposed on” and “over” may be used to indicate that two or more elements are in direct physical contact with one another. Also, the term “on,”, “overlying,” “disposed on,” and “over”, may mean that two or more elements are not in direct contact with one another. For example, “over” may mean that one element is above another element while not contacting one another and may have another element or elements in between the two elements.

In various embodiments, novel device structures and techniques are provided for forming a bidirectional TVS device.

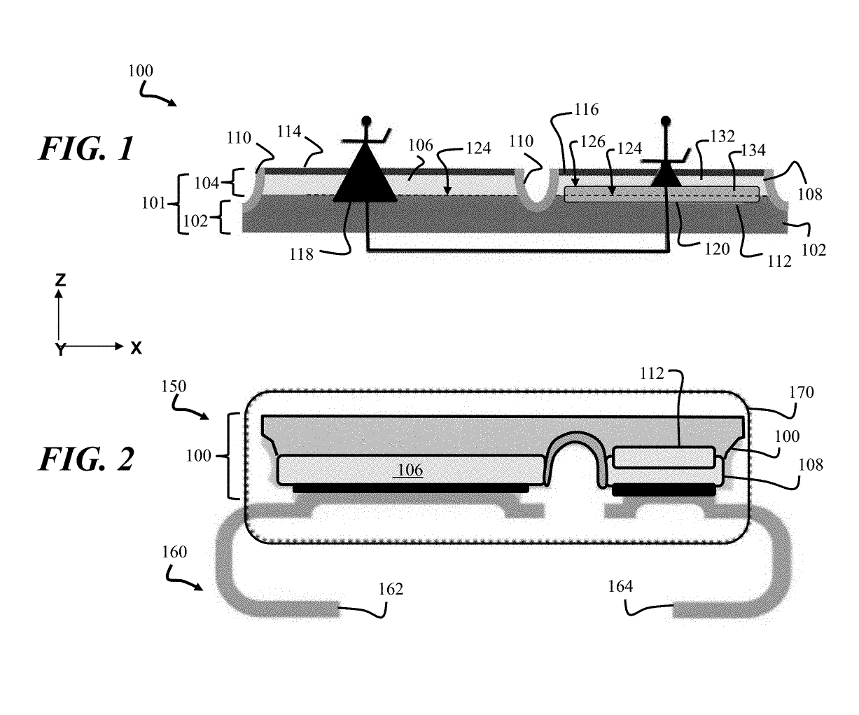

FIG. 1 illustrates a TVS device 100 according to embodiments of the disclosure. The TVS device 100 may include a substrate base 102 formed in a substrate 101. The substrate base 102 may be formed of a semiconductor of a first conductivity type, such as a P-type semiconductor. The TVS device 100 may further include an epitaxial layer 104, disposed on the substrate base 102, on a first side of the substrate 101 (top side in FIG. 1) as shown. The epitaxial layer 104 may be formed of a semiconductor of a second conductivity type. For example, when the substrate base 102 is P-type silicon, the epitaxial layer may be N-type silicon. For example, when the substrate base 102 is N-type silicon, the epitaxial layer may be P-type silicon. As such, a P/N junction may be formed at the interface 124 between the substrate base 102 and epitaxial layer 104. The epitaxial layer 104 may further comprise a first epitaxial portion 106 and a second epitaxial portion 108. As shown, the first epitaxial portion 106 and the second epitaxial portion 108 are disposed on a first side of the substrate 101. The first epitaxial portion 106 is electrically isolated from the second epitaxial portion 108, by virtue of an isolation structure 110. As shown, the isolation structure 110 extends from the surface of the first side of the substrate 101 into the substrate base 102. The isolation structure 110 may be formed in a known manner, such as using a trench insulator.

As such, the first epitaxial portion 106 forms a first diode 118, in conjunction with the substrate base 102. As such, the second epitaxial portion 108 forms a second diode 120, in conjunction with the substrate base 102. According to various embodiments of the disclosure, the first diode 118 differs from the second diode 120 in breakdown voltage, or a combination of breakdown voltage and power capacity. For example, as detailed below, by virtue of an upper region 132 of the second epitaxial portion 108 of the epitaxial layer 104 having a relatively lesser thickness as compared to the first epitaxial portion 106, the breakdown voltage of the second epitaxial portion 108 may be lower as compared to the breakdown voltage of the first epitaxial portion 106. For example, the first layer thickness of the first epitaxial portion 106 may be between 20 μm and 80 μm in some embodiments, while for a given first layer thickness of the first epitaxial portion 106, the thickness of the upper region 132 may be less than the given first layer thickness.

As further shown in FIG. 1, the first diode 118 and the second diode 120, formed within the substrate 101, are arranged in electrical series in an anode-to-anode configuration. The respective cathodes of the first diode 118 and the second diode 120 may be electrically contacted through contact 114 and contact 116, respectively, formed on the first side of the substrate 101. As such, the TVS device 100 may form an asymmetric single sided bi-directional device, where both diodes are formed on the same side of the substrate 101.

The degree of voltage asymmetry between the first diode 118 and the second diode 120 may be arranged by adjusting the relative thickness of the first layer thickness of first epitaxial portion 106 as compared to the second layer thickness of the second epitaxial portion 108. For example, in various embodiments, the epitaxial layer 104 is initially formed as a blanket layer on the substrate base 102, so the dopant level of a dopant of a first conductivity is the same in the epitaxial layer 104 in different regions within the X-Y plane, such as in the first epitaxial portion 106 and the second epitaxial portion 108. While the first epitaxial portion 106 may remain unaltered, after the initial formation of the epitaxial layer 104 with a uniform thickness, the second epitaxial portion 108 of epitaxial layer 104 may be selectively treated in a manner to reduce the thickness of the portion of the epitaxial layer 104 that has the dopant of the first conductivity type second epitaxial portion 108. In particular, a buried diffusion region 112 may be formed in the region between the substrate base 102 and the epitaxial layer 104.

In various embodiments, the buried diffusion region 112 may be formed in different processes. In one example, the buried diffusion region 112 may be formed by ion implantation at an appropriate ion energy and ion dose. The presence of the buried diffusion region 112 effectively reduces the thickness of the portion of the second epitaxial portion 108 of a first conductivity type, as compared to the thickness of first epitaxial portion 106 having the first conductivity type. In the case where the epitaxial layer 104 is n-doped, by placing a p-type dopant region (buried diffusion region 112) in the lower portion of the epitaxial layer 104 in second epitaxial region 108, the thickness of the epitaxial layer 104 having n-type conductivity is reduced. In particular, the location of the P/N junction is shifted from the interface 124 of the substrate base 102 and epitaxial layer 104 (see first epitaxial portion 106), to the interface between the epitaxial layer 104 and the buried diffusion region 112, shown as interface 126. Said differently, the second epitaxial portion 108 as shown in FIG. 1 includes an upper region 132 that is formed of the second conductivity type, and a lower region 134, formed of a first conductivity type by virtue of the formation of the buried diffusion region 112.

In particular, the buried diffusion region 112 may comprise a p-dopant having a p-dopant concentration, wherein the epitaxial layer 104 comprises an n-dopant having an n-dopant concentration, wherein the p-dopant concentration is greater than the n-dopant concentration. Said differently, the buried diffusion region 112 may be a counterdoped region within the epitaxial layer 104, where, by virtue of the -dopant concentration exceeding the original n-dopant concentration of the epitaxial layer 104, the counterdoped region exhibits a p-type conductivity.

Of course, the buried diffusion region 112, to the extent of overlapping the substrate base 102, may locally increase the p-concentration of the substrate base 102. In various embodiments, the buried diffusion region 112 may be more heavily doped that the substrate base 102. In other words, the buried diffusion region 112 may comprise a first dopant concentration level, wherein the substrate base 102 comprises a second dopant concentration level, less than the first dopant concentration level.

In some examples, according to different embodiments of the disclosure the first diode 118 may exhibit a breakdown voltage that is substantially greater than the breakdown voltage of the second diode 120. For example, the first diode may exhibit a breakdown voltage of 300 V or greater, and the second diode 120 may exhibit a breakdown voltage of 100 V or less. The absolute breakdown voltages for the first diode 118 and the second diode 120, as well as the degree of breakdown voltage asymmetry (the breakdown voltage difference between first diode 118 and second diode 120) may be adjusted by adjusting the thickness of the epitaxial layer 104, the dopant concentration of the epitaxial layer 104, the dopant concentration in the buried diffusion region 112, and other factors. For example, if the first diode 118 is formed with a first layer thickness of 60 μm and a breakdown voltage of 600 V, the second diode 120 may be formed by setting the thickness of upper region 132 by forming the buried diffusion region 112 in the second epitaxial portion 108 at 30 μm, in order to yield a breakdown voltage of much less than 600V.

In additional embodiments, the power capacity of the first diode 118 and second diode 120 may be set to be different from one another. The power capacity may be adjusted by adjusting the areas of the first epitaxial portion 106 and the second epitaxial layer 108 within the plane (X-Y plane of the Cartesian coordinate system shown) of the substrate 101. The areas may be adjusted by forming masks of different sizes to define the first epitaxial portion 106 and second epitaxial portion 108, according to known techniques in the art. For example, the first diode 118 may exhibit a power capacity of 700 W or greater, and the second diode may exhibit a power capacity of 500 W or less. The embodiments are not limited in this context

An advantage of the design of FIG. 1 for an asymmetric device is that a leadframe may be attached to just one side of the substrate 101, in order to contact the different diodes. FIG. 2 illustrates a TVS device assembly 150. The TVS device assembly 150 may include the TVS device 100 and leadframe 160, where the leadframe 160 contacts the first surface of the TVS device 100, meaning the upper surface of FIG. 1. In this example, the leadframe 160 may include a first part 162, where the first part 162 is connected to the first epitaxial portion 106 of the TVS device 100, and may include a second part 164, coupled to the second epitaxial portion 108 of the TVS device 100. In the example of FIG. 2 the TVS assembly includes a housing 170, which housing may be a molded package. The leadframe 160 may be conveniently attached to the TVS device 100 by soldering or other bonding method.

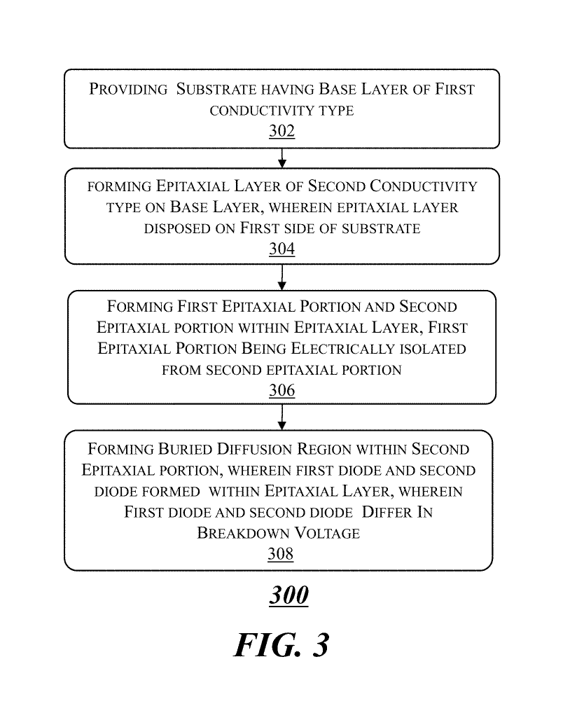

FIG. 3 depicts an exemplary process flow 300 according to embodiments of the disclosure. At block 302, a substrate is provided, where the substrate includes a base layer of a first conductivity type. The substrate may be, for example, a p-type silicon substrate where the base layer represents the substrate itself. At block 304, an epitaxial layer of a second conductivity type is formed on the base layer, wherein the epitaxial layer is disposed on a first side of the substrate. As such, the epitaxial layer may be n-type silicon when the substrate base in p-type silicon. The epitaxial layer may be formed according to known deposition methods. The dopant concentration in the epitaxial layer and layer thickness of the epitaxial layer may be designed according to electrical properties for a diode to be formed in the substrate. In various embodiments, the layer thickness of the epitaxial layer may range from 20 μm to 80 μm. The embodiments are not limited in this context.

At block 306 a first epitaxial portion and a second epitaxial portion are formed within the epitaxial layer, where the first epitaxial portion is electrically isolated from the second epitaxial portion. The first epitaxial portion and second epitaxial portion may be formed by generating isolation structure(s) according to known techniques, where the isolation structures extend through the entirety of the epitaxial layer.

At block 308, a buried diffusion region is formed within the second epitaxial portion, wherein the first diode and second diode differ in breakdown voltage. In particular, the buried diffusion region may be formed of a first dopant type, while the epitaxial layer that includes the second epitaxial portion is formed of a second dopant type. The buried diffusion region may extend at least to the interface between the substrate base and the epitaxial layer and may extend within the second epitaxial portion, while not extending to an upper surface of the second epitaxial portion. In this manner, the buried diffusion region may act to shift the location of a P/N junction from an interface of the substrate base and epitaxial layer, to the interface between the epitaxial layer and the upper surface of the buried diffusion region. This shifting reduces the thickness of the semiconductor layer of the first conductivity type on the cathode side of the diode, where the reduced thickness may accordingly reduce the breakdown voltage.

While the present embodiments have been disclosed with reference to certain embodiments, numerous modifications, alterations and changes to the described embodiments are possible while not departing from the sphere and scope of the present disclosure, as defined in the appended claims. Accordingly, the present embodiments are not to be limited to the described embodiments, and may have the full scope defined by the language of the following claims, and equivalents thereof.

What is claimed is:

1. A transient voltage suppression (TVS) device, comprising:
a substrate base formed in a substrate, the substrate base comprising a semiconductor of a first conductivity type; and
an epitaxial layer, comprising a first thickness, and disposed on the substrate base, on a first side of the substrate, the epitaxial layer further comprising:
a first epitaxial portion, the first epitaxial portion comprising the first thickness, and being formed of a semiconductor of a second conductivity type;
a second epitaxial portion, the second epitaxial portion comprising an upper region, the upper region formed of the second conductivity type, and having a second thickness less than the first thickness,
wherein a buried diffusion region is disposed in a lower portion of the epitaxial layer in the second epitaxial region, the buried diffusion region being formed of a semiconductor of the first conductivity type,
and wherein the first portion is electrically isolated from the upper region of the second portion.

2. The TVS device of claim 1, wherein the first portion forms a first diode, wherein the second portion forms a second diode, and wherein the first diode differs from the second diode in breakdown voltage, or a combination of breakdown voltage and power capacity.

3. The TVS device of claim 2, wherein the first diode and the second diode are arranged in electrical series, anode-to-anode.

4. The TVS device of claim 1, wherein the first thickness is between 20 μm to 80 μm.

5. The TVS device of claim 1, wherein the buried diffusion region extends into the substrate base.

6. The TVS device of claim 1, wherein the buried diffusion region comprises a first dopant concentration level, and wherein the substrate base comprises a second dopant concentration, less than the first dopant concentration.

7. The TVS device of claim 1, wherein the buried diffusion region comprises a p-dopant having p-dopant concentration, wherein the epitaxial layer comprises an n-dopant having an n-dopant concentration, wherein the p-dopant concentration is greater than the n-dopant concentration, wherein the buried diffusion region comprises a counterdoped region within the epitaxial layer, the counterdoped region comprising a p-type conductivity.

8. The TVS device of claim 2, wherein the first diode comprises a breakdown voltage of 300 V or greater, and wherein the second diode comprises a breakdown voltage of 100 V or less.

9. The TVS device of claim 2, wherein the first diode comprises a power capacity of 700 W or greater, and wherein the second diode comprises a power capacity of 500 W or less.

10. A transient voltage suppression (TVS) device assembly, comprising:
a TVS device, the TVS device comprising:
a substrate base formed in a substrate, the substrate base comprising a semiconductor of a first conductivity type;
an epitaxial layer, comprising a first thickness, and disposed on the substrate base, on a first side of the substrate, the epitaxial layer further comprising:
a first epitaxial portion, the first epitaxial portion comprising the first thickness, and being formed of a semiconductor of a second conductivity type;
a second epitaxial portion, the second epitaxial portion comprising an upper region, the upper region formed of the second conductivity type, and having a second thickness less than the first thickness,
wherein a buried diffusion region is disposed in a lower region of the epitaxial layer in the second epitaxial portion, the buried diffusion region being formed of a semiconductor of the first conductivity type; and
a leadframe, the leadframe being coupled to the TVS device on the first side of the substrate.

11. The TVS device assembly of claim 10, wherein the leadframe is disposed on just the first side of the TVS device.

12. The TVS device assembly of claim 10, wherein the first epitaxial portion is electrically isolated from the second portion.

13. The TVS device assembly of claim 10, wherein the first epitaxial portion forms a first diode, wherein the second epitaxial portion forms a second diode, and wherein the first diode differs from the second diode in breakdown voltage.

14. The TVS device assembly of claim 13, wherein the first diode and the second diode are arranged in electrical series, anode-to-anode.

15. A method, comprising:
providing a substrate having a base layer of a first conductivity type;
forming an epitaxial layer of a second conductivity type on the base layer, wherein the epitaxial layer is disposed on a first side of the substrate, and having a first thickness;
forming a first epitaxial portion and a second epitaxial portion within the epitaxial layer, wherein the first epitaxial portion is electrically isolated from the second epitaxial portion; and
forming a buried diffusion region in the second epitaxial portion, the buried diffusion region extending at least to an interface between the epitaxial layer and the substrate base, wherein the buried diffusion region comprises the first conductivity type, wherein the buried diffusion region defines an upper region of the second epitaxial portion, the upper region comprising the second conductivity type, and having a second thickness less than the first thickness.

16. The method of claim 15, wherein the buried diffusion region is formed by ion implantation.

17. The method of claim 15, wherein the buried diffusion region comprises a p-dopant having p-dopant concentration, wherein the epitaxial layer comprises an n-dopant having an n-dopant concentration, wherein the p-dopant concentration is greater than the n-dopant concentration, wherein the buried diffusion region comprises a counterdoped region within the epitaxial layer, the counterdoped region comprising a p-type conductivity.

18. The method of claim 15, further comprising adjoining a lead frame to the substrate, wherein the leadframe is disposed just on the first side of the substrate.
